(19) United States
(12) Patent Application Publication
(10) Pub. No.: US 2026/0107756 A1
(43) Pub. Date: Apr. 16, 2026

(54) SEMICONDUCTOR DEVICE

(71) Applicant: Socionext Inc., Kanagawa (JP)

(72) Inventors: Atsushi OKAMOTO, Yokohama (JP); Hirotaka TAKENO, Yokohama (JP); Wenzhen WANG, Yokohama (JP)

(21) Appl. No.: 19/409,433

(22) Filed: Dec. 4, 2025

Related U.S. Application Data
(63) Continuation of application No. PCT/JP2023/021509, filed on Jun. 9, 2023.

(51) Int. Cl. H10W 20/43; H10W 20/42

(52) U.S. Cl. CPC H10W 20/43; H10W 20/42

(57) ABSTRACT

A semiconductor device includes a substrate; a first power supply line and a second power supply line both formed below an upper surface of the substrate and to which a first potential and a second potential are respectively supplied; a first control line formed below the upper surface of the substrate; a first transistor formed below the upper surface of the substrate, provided electrically between the first and power supply lines, and having a gate electrically connected to the first control line; a tap cell including a semiconductor layer formed on the substrate and a via formed in the substrate, arranged at a position overlapping the semiconductor layer and the first control line in a plan view, and connected to the semiconductor layer and the first control line; and a control circuit formed on the substrate and electrically connected to the via.

### CROSS-REFERENCE TO RELATED APPLICATIONS

This application is a continuation application of International Application No. PCT/JP2023/021509 filed on Jun. 9, 2023, and designated the U.S., the entire contents of which are incorporated herein by reference.

### BACKGROUND

### Technical Field

The present disclosure relates to a semiconductor device.

### Description of Related Art

It is known to provide a power switch circuit for switching a power supply between supplying and shutting off power to a transistor in a semiconductor device such as a standard cell. A backside power delivery network (BSPDN) technology in which a power supply line is provided on a back surface of a semiconductor substrate and power is supplied to a transistor provided on a front surface of the semiconductor substrate via a through silicon via (TSV). A technology of directly coupling vias to a source and a drain of a transistor provided on the front surface of a semiconductor substrate from the back surface of the semiconductor substrate is known.

Patent Document 1: U.S. Patent Application Publication No. 2022/0344263

Patent Document 2: U.S. Patent Application Publication No. 2022/0208757

Patent Document 3: U.S. Patent Application Publication No. 2021/0272903

Patent Document 4: U.S. Patent Application Publication No. 2019/0305773

Patent Document 5: International Publication No. WO 2020/065916

Patent Document 6: International Publication No. WO 2020/066797

Patent Document 7: International Publication No. WO 2021/111604

Patent Document 8: International Publication No. WO 2021/079511

Patent Document 9: International Publication No. WO 2021/070367

Patent Document 10: International Publication No. WO 2021/070366

### SUMMARY

According to one aspect of the present disclosure, a semiconductor device includes a substrate; a first power supply line to which a first potential is supplied and a second power supply line to which a second potential is supplied, the first power supply line and the second power supply line being formed below an upper surface of the substrate; a first control line formed below the upper surface of the substrate; a first transistor formed below the upper surface of the substrate, provided electrically between the first power supply line and the second power supply line, and having a gate electrically connected to the first control line; a tap cell including a semiconductor layer formed on the substrate and a via formed in the substrate, arranged at a position overlapping the semiconductor layer and the first control line in a plan view, and connected to the semiconductor layer and the first control line; and a control circuit formed on the substrate and electrically connected to the via.

### BRIEF DESCRIPTION OF THE DRAWINGS

FIG. 1 is a plan view illustrating an example of a layout in a semiconductor device according to a first embodiment;

FIG. 2 is a cross-sectional view illustrating an example of a cross-sectional structure of the semiconductor device of FIG. 1;

FIG. 3 is a circuit diagram illustrating an example of a circuit arranged in a standard cell block of FIG. 1;

FIG. 4 is a plan view illustrating an outline of a layout of circuits and wirings of FIG. 3;

FIG. 5 is a plan view illustrating an outline of a layout of the circuits and wirings of FIG. 3 in another layer;

FIG. 6 is a plan view illustrating an example of a layout of the circuits and wirings illustrated in FIGS. 4 and 5;

FIG. 7 is a cross-sectional view illustrating an example of a cross section taken along line X1-X1′ and line X2-X2′ in FIG. 6;

FIG. 8 is a cross-sectional view illustrating another example of a cross section taken along line X1-X1′ in FIG. 6;

FIG. 9 is a plan view illustrating a first modified example of a layout of the circuits and wirings illustrated in FIGS. 4 and 5;

FIG. 10 is a plan view illustrating a second modified example of a layout of the circuits and wirings illustrated in FIGS. 4 and 5;

FIG. 11 is a plan view illustrating a third modified example of a layout of the circuits and wirings illustrated in FIGS. 4 and 5;

FIG. 12 is a cross-sectional view illustrating an example of a cross section taken along line X3-X3′ and line X4-X4′ in FIG. 11;

FIG. 13 is a plan view illustrating an example of a layout of circuits and wirings of a standard cell block in a semiconductor device according to a second embodiment;

FIG. 14 is a plan view illustrating an outline of a layout of circuits and wirings of a standard cell block in a semiconductor device according to a third embodiment; and

FIG. 15 is a cross-sectional view illustrating an example of a layout of circuits and wirings of a standard cell block in a semiconductor device according to a fourth embodiment.

### DETAILED DESCRIPTION

Specific studies have not been conducted regarding how to arrange wirings and vias used for connections between a power switch circuit provided on a back surface of a semiconductor substrate and circuits provided on a front surface of the semiconductor substrate while suppressing an increase in the circuit area.

According to the disclosed technology, when a power switch circuit is provided on a back surface of a substrate, an increase in the circuit area can be suppressed.

Hereinafter, embodiments will be described with reference to the drawings. In the descriptions hereinafter, a symbol indicating a signal is also used as a symbol indicating a signal line or a signal terminal. A symbol indicating a power supply potential is also used as a symbol indicating a power supply line or a power supply terminal to which the power supply potential is supplied.

### First Embodiment

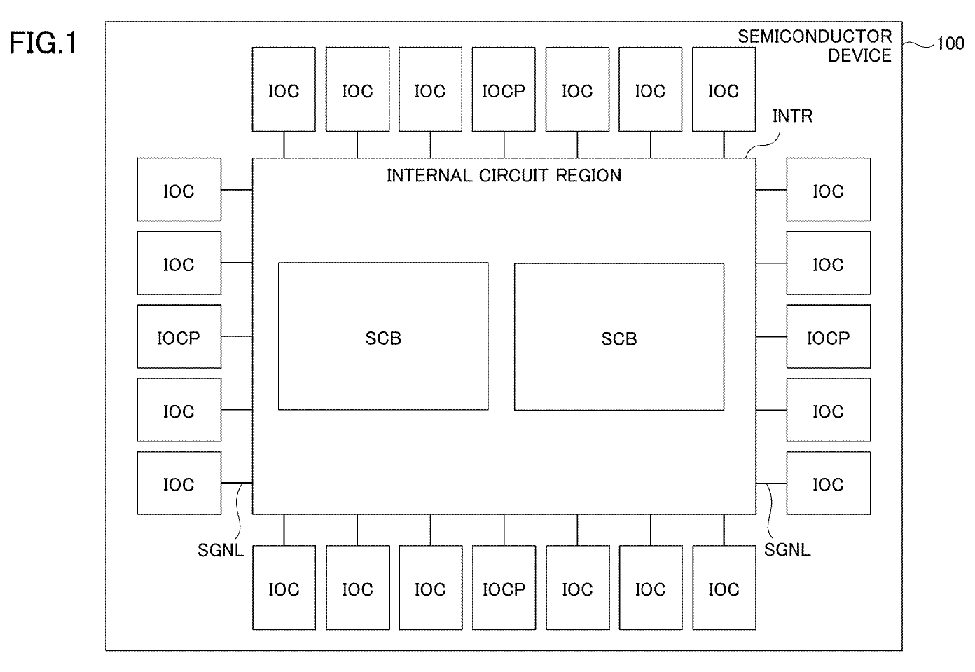

FIG. 1 illustrates an example of a layout in a semiconductor device according to the first embodiment. For example, a semiconductor device 100 illustrated in FIG. 1 may be a system-on-a-chip (SoC), a single field-programmable gate array (FPGA), or the like.

The semiconductor device 100 includes a plurality of I/O cells IOC and IOCP and an internal circuit region INTR. The I/O cell IOC is an interface circuit for a signal SGNL, such as an input signal, an output signal, or an input/output signal. The I/O cell IOCP is an interface circuit for a power supply potential or a ground potential.

The I/O cells IOC and IOCP are connected to the internal circuit region INTR. For example, the internal circuit region INTR includes one or more standard cell blocks SCB in which standard cells are provided. In the internal circuit region INTR, a logic circuit other than the standard cell may be included, or a memory may be included. A memory may be included in the standard cell block SCB.

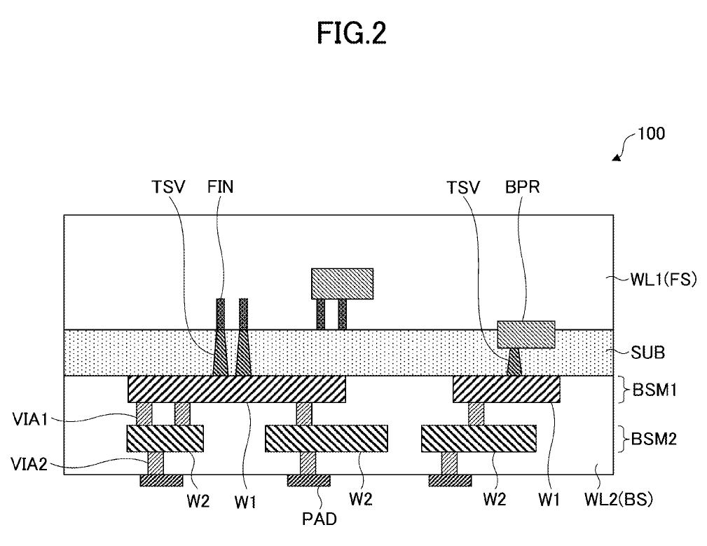

FIG. 2 illustrates an example of a cross-sectional structure of the semiconductor device 100 of FIG. 1. The semiconductor device 100 includes a substrate SUB, a wiring layer WL1 formed on a front surface side FS of the substrate SUB, and a wiring layer WL2 formed on a back surface side BS of the substrate SUB. The front surface side FS of the substrate SUB is an example of an upper surface of the substrate SUB or a side above the substrate SUB, and the back surface side BS of the substrate SUB is an example of a side below the substrate SUB. A fin FIN, which is a part of a transistor, is formed on the surface of the substrate SUB. The fin FIN has a source, a drain, and a channel. A pad PAD, which is an external connection terminal, is formed on the surface (back surface) of the wiring layer WL2 opposite to the substrate SUB.

The wiring layer WL2 includes a plurality of wiring layers BSM1 and BSM2 (two layers in FIG. 2, and BSM is an abbreviation of “backside metal”). For example, the wiring layers BSM1 and BSM2 are respectively formed with wirings W1 and W2 that respectively supply a power supply potential and a ground potential. The wirings W1 and W2 are connected to each other through a via VIA1. The wiring W2 and the pad PAD are connected to each other through a via VIA2.

The wiring W1 is connected to the source and the drain of the fin FIN via a through silicon via (TSV) formed in the substrate SUB. The wiring W1 may be connected to a buried power rail (BPR) buried in the substrate SUB via the TSV. The TSV is an example of a via.

The transistor formed on the substrate SUB is not limited to a fin field effect transistor (FET) using a fin. For example, the transistor formed on the substrate SUB may be a planar metal oxide semiconductor FET (MOSFET), a nanosheet FET, or a complementary FET (CFET). In the planar MOSFET and the nanosheet FET, the TSV that supplies a power supply potential or a ground potential is connected to the source and the drain of the transistor. In the case of the CFET, the TSV that supplies a power supply potential or a ground potential may be connected to the source and the drain located closest to the substrate SUB.

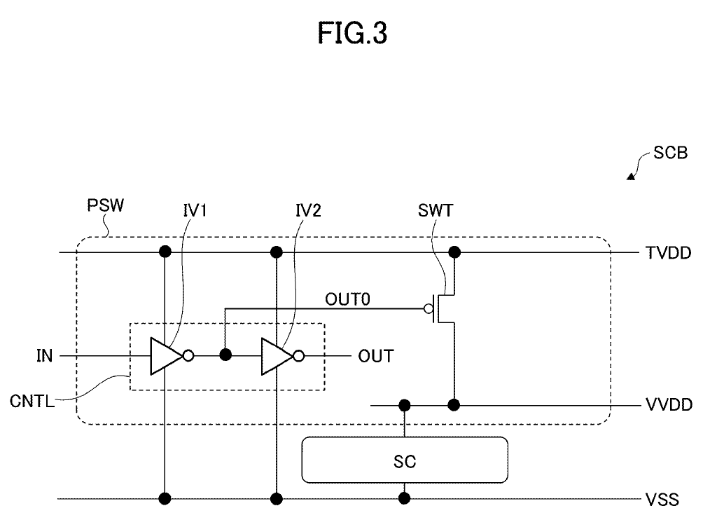

FIG. 3 illustrates an example of a circuit arranged in the standard cell block SCB of FIG. 1. The standard cell block SCB includes a power switch circuit PSW and a standard cell SC. The standard cell SC is connected to a virtual power supply line VVDD and a ground line VSS, and operates upon receipt of a supply of a virtual power supply potential VVDD from the virtual power supply line VVDD.

The power switch circuit PSW includes a control circuit CNTL and a switch transistor SWT. The control circuit CNTL is a buffer circuit having inverters IV1 and IV2 connected in series between an input signal line IN and an output signal line OUT. The inverters IV1 and IV2 are connected to a power supply line TVDD and the ground line VSS and operate. The inverter IV1 inverts the logic of an input signal IN and outputs an inverted signal as an output signal OUT0. The inverter IV2 inverts the logic of the output signal OUT0 that is output from the inverter IV1, and outputs an inverted signal as an output signal OUT.

The switch transistor SWT is a PMOS transistor having a source connected to the power supply line TVDD and a drain connected to the virtual power supply line VVDD, and operates upon receipt of a voltage of the output signal OUT0 that is output from the control circuit CNTL as a gate potential. While the switch transistor SWT is in an on state, the power supply line TVDD and the virtual power supply line VVDD are electrically connected to each other, and a power supply potential TVDD is supplied to the standard cell SC via the virtual power supply line VVDD.

While the switch transistor SWT is in an off state, an electrical connection between the power supply line TVDD and the virtual power supply line VVDD is shut off, and the virtual power supply line VVDD is set to a floating state. Instead of the output of the inverter IV1, the input IN of the inverter IV1 or the output OUT of the inverter IV2 may be connected to the gate of the switch transistor SWT. This is the same in other embodiments.

The control circuit CNTL may be arranged in a region different from the region where the power switch circuit PSW is arranged. The output signal OUT may be supplied to the input terminal IN of another power switch circuit PSW. The switch transistor SWT is an example of a first transistor formed below the upper surface of the substrate SUB and electrically provided between the power supply line TVDD and the virtual power supply line VVDD.

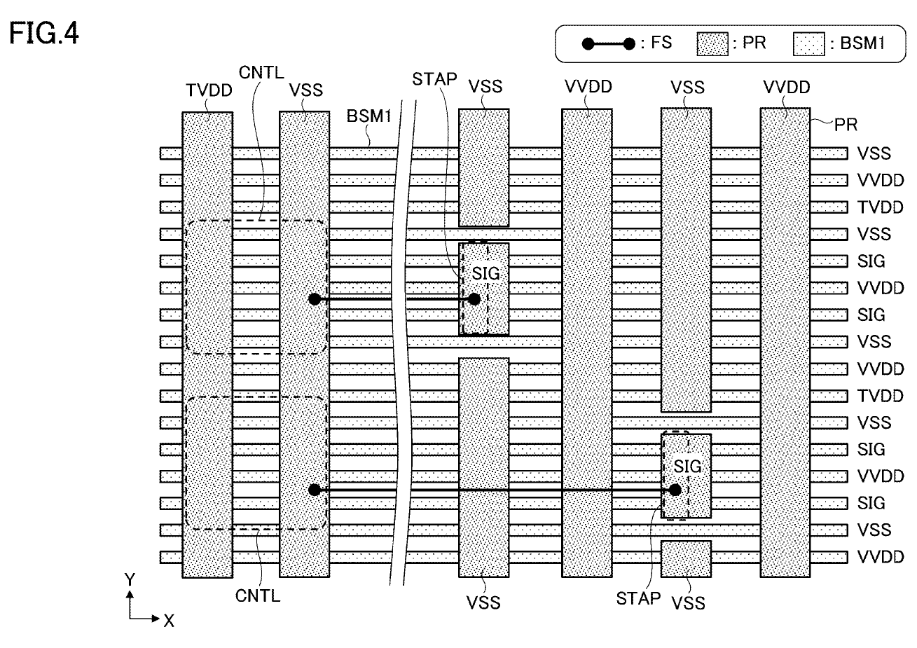

FIG. 4 illustrates an outline of a layout of the circuits and wirings of FIG. 3. In FIG. 4, among the circuits and wirings of FIG. 3, a wiring FS (Front Side) on the front surface side of the substrate SUB, the wiring of a PR (Power Rail) layer provided in the substrate SUB, the wiring of the wiring layer BSM1 provided on the back surface side of the substrate SUB, and the positions of the control circuit CNTL and a signal tap cell STAP are illustrated in a plan view.

In the wiring layer PR, the wiring (power supply line TVDD, ground line VSS, virtual power supply line VVDD, signal line SIG) extending in the Y direction is arranged side by side in the X direction. The ground line VSS extending in the Y direction is interrupted at a plurality of locations partway along the ground line VSS, and the signal line SIG is arranged at the interrupted positions. In other words, the signal line SIG is arranged between the plurality of ground lines VSS in the Y direction. For example, the output signal OUT0 that is output from the inverter IV1 in FIG. 3 is transmitted to the signal line SIG.

The signal line SIG of the wiring layer PR is an example of a first control line. The power supply line TVDD of the wiring layer PR is an example of a first power supply line, and the power supply potential TVDD is an example of a first potential. The virtual power supply line VVDD of the wiring layer PR is an example of a second power supply line, and the virtual power supply potential VVDD is an example of a second potential. The ground line VSS of the wiring layer PR is an example of a third power supply line.

The control circuit CNTL is arranged at a position overlapping the region in which the power supply line TVDD and the ground line VSS of the wiring layer PR are arranged in a plan view. The signal tap cell STAP is arranged at a position overlapping a region in which the signal line SIG of the wiring layer PR is arranged in a plan view.

For example, as illustrated in FIG. 4, the control circuit CNTL and the signal tap cell STAP may be arranged at separate positions or adjacent to each other. The control circuit CNTL may be arranged in a power supply domain (constant power supply region) to which the power supply potential TVDD is always supplied, and the signal tap cell STAP may be arranged in a power supply domain (power supply shutoff region) in which the supply of the virtual power supply potential VVDD can be stopped.

The wirings (virtual power line VVDD, power line TVDD, ground line VSS, signal line SIG) of the wiring layer BSM1 are arranged below the wiring layer PR. The wirings of the wiring layer BSM1 extend in the X direction and are arranged side by side in the Y direction. In the wirings of the wiring layer BSM1 and the wirings of the wiring layer PR, the same type of wirings (e.g., VSS to VSS or TVDD to TVDD) are connected in common. The control circuit CNTL and the signal tap cell STAP are connected to each other by the wiring FS.

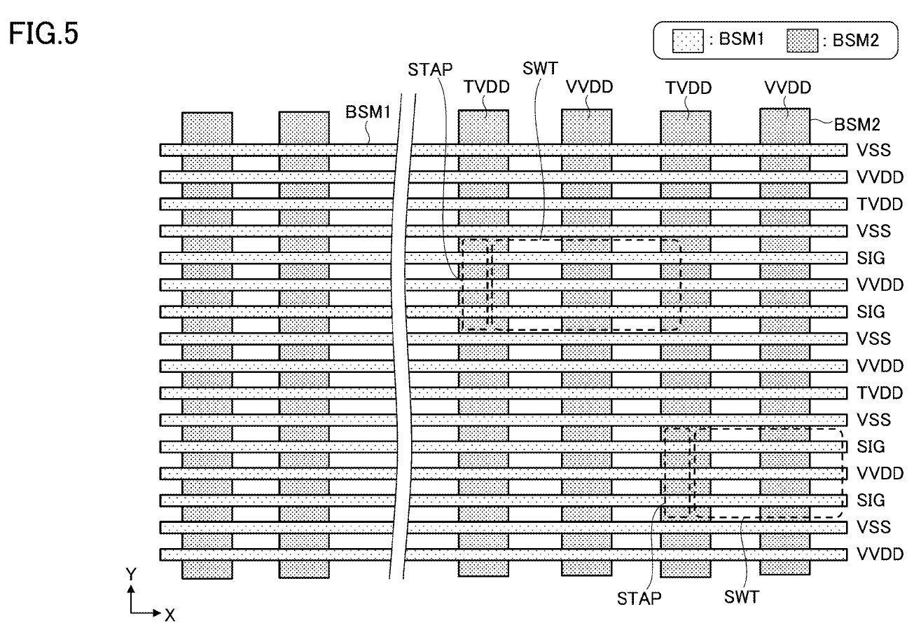

FIG. 5 illustrates an outline of a layout of the circuits and wirings of FIG. 3 in another layer. FIG. 5 illustrates a region that overlaps the region illustrated in FIG. 4 in a plan view, and illustrates, among the circuits and wirings of FIG. 3, the wirings of the wiring layers BSM1 and BSM2 provided on the back surface side of the substrate SUB, and the positions of the signal tap cell STAP and the switch transistor SWT.

The wirings (virtual power line VVDD, power line TVDD, etc.) of the wiring layer BSM2 extend in the Y direction and are arranged side by side in the X direction. The switch transistor SWT is arranged at a position adjacent to the signal tap cell STAP in a plan view. Since the signal line SIG extends in the X direction in the wiring layer BSM1, the signal tap cell STAP and the switch transistor SWT may be arranged at positions separated from each other in a plan view.

Although the position of the control circuit CNTL is omitted in FIG. 5 because only the layer on the back side of the substrate SUB is illustrated, the position of the control circuit CNTL is the same as in FIG. 4. The type of wiring of the wiring layer BSM2 that overlaps the control circuit CNTL in a plan view is not limited to the power supply line TVDD and the ground line VSS of the wiring layer PR illustrated in FIG. 4.

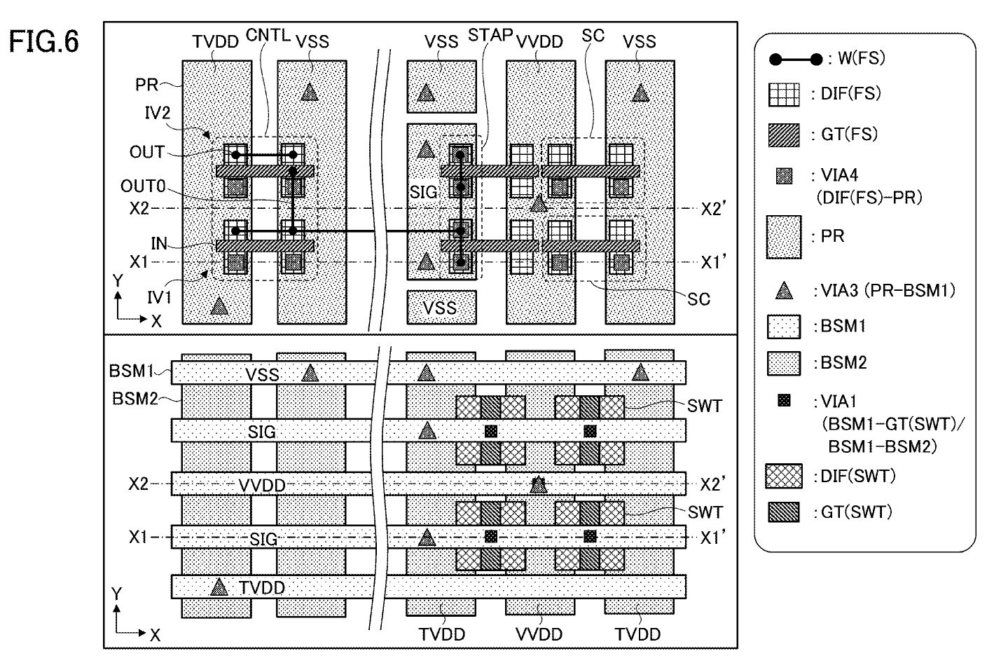

FIG. 6 illustrates an example of the layout of the circuits and wirings illustrated in FIGS. 4 and 5. The layout illustrated in the upper part of FIG. 6 illustrates the layout above the wiring layer PR except for the via VIA3. The layout illustrated in the lower part of FIG. 6 illustrates the layout below the substrate SUB.

In the legends illustrated in FIG. 6 and the subsequent plan views, the symbol “W(FS)” denotes a signal wiring provided on the front surface side of the substrate SUB. The symbol “DIF(FS)” denotes a semiconductor layer, such as a diffusion layer, provided on the front surface side of the substrate. The symbol “GT(FS)” denotes a gate of a transistor provided on the front surface side of the substrate.

The symbol “VIA4” denotes a via connecting the semiconductor layer DIF(FS) and the wiring of the wiring layer PR. The symbol “PR” denotes a wiring provided in the wiring layer PR. The symbol “VIA3” denotes a via connecting the wiring of the wiring layer PR and the wiring of the wiring layer BSM1. The symbol “BSM1” denotes a wiring provided in the wiring layer BSM1. The symbol “BSM2” denotes a wiring provided in the wiring layer BSM2.

The symbol “VIA1” denotes a via connecting a wiring in the wiring layer BSM1 and a gate GT(SWT) of the switch transistor SWT, or a via connecting a wiring in the wiring layer BSM1 and a wiring in the wiring layer BSM2. The symbol “DIF(SWT)” denotes a semiconductor layer (diffusion layer) of the switch transistor SWT. The symbol “GT(SWT)” denotes a gate of the switch transistor SWT.

A transistor including a semiconductor layer DIF(FS) and a gate GT(FS) is formed on the substrate SUB. The control circuit CNTL includes, for example, two-stage inverters IV1 and IV2 as illustrated in FIG. 3. The output of the first-stage inverter IV1 is connected to the gate GT(SWT) of the switch transistor SWT via the wiring W(FS), the semiconductor layer DIF(FS) of the signal tap cell STAP, the via VIA4, the wiring SIG of the wiring layer PR, the via VIA3, the wiring SIG of the wiring layer BSM1, and the via VIA1.

The wiring SIG of the PR layer is arranged in a region where the ground line VSS of the PR layer extending in the Y direction is interrupted and where the signal tap cell STAP is arranged. In other words, the ground line VSS of the PR layer is arranged in such a manner that the region where the signal tap cell STAP is arranged is avoided. Thus, as a result, compared with the case where the wiring SIG of the PR layer is extended in the Y direction without interruption, the region where the ground line VSS is arranged can be increased and the ground resistance can be reduced.

The transistor of the control circuit CNTL is, for example, a fin FET (field effect transistor) using fins, a planar MOSFET (metal oxide semiconductor FET), a nanosheet FET, or a CFET (complementary FET). The ground potential VSS or the power supply potential TVDD is supplied to the transistor of the control circuit CNTL from the wiring of the wiring layer PR via the via VIA4, which is directly connected to the source and the drain, which are the semiconductor layers of the transistor.

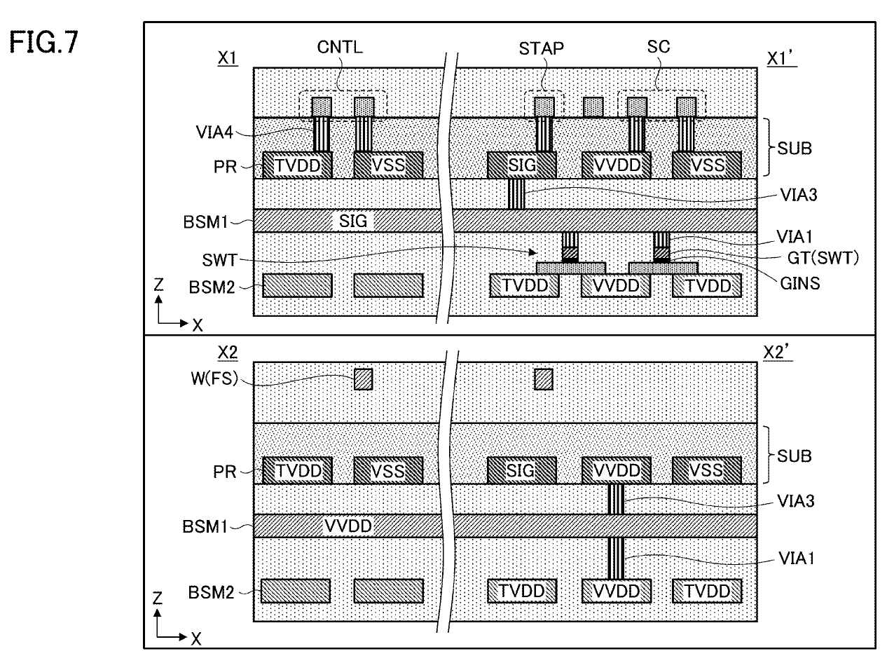

For example, the switch transistor SWT is located in a region where the virtual power supply line VVDD and the ground line VSS of the wiring layer PR are arranged in a plan view, and overlaps the standard cell SC (for example, an inverter) in a plan view. The switch transistor SWT is arranged between the wiring layers BSM1 and BSM2 as illustrated in FIG. 7.

The control circuit CNTL is located in a region where the power supply line TVDD and the ground line VSS of the wiring layer PR are arranged. The wiring of the wiring layer PR connected to the control circuit CNTL and the wiring of the wiring layer PR connected to the signal tap cell STAP may be arranged at an interval or adjacent to each other as illustrated in FIG. 6.

As a method for transmitting the signal SIG (output signal OUT0) from the control circuit CNTL to the switch transistor SWT on the back surface of the substrate SUB, it is conceivable to form a via, such as TSV, in a region on the front surface side of the substrate SUB where no transistor is provided. In this case, the via must be formed in a region different from the circuit region (transistor region), which may increase the circuit area.

On the other hand, in this embodiment, the signal tap cell STAP is provided in the circuit region on the front surface side of the substrate SUB where the transistor is provided by using the via VIA4 directly connected to the semiconductor layer, such as the source and drain of the transistor, from the back surface side of the substrate SUB. Therefore, even when the switch transistor SWT is arranged on the back surface of the substrate SUB, the signal SIG from the control circuit CNTL can be supplied to the gate of the switch transistor SWT without providing a region different from the circuit region, and the increase in the circuit area can be suppressed.

The signal SIG (output signal OUT0) is supplied from the control circuit CNTL to the gate GT(SWT) of the switch transistor SWT by using the wiring W provided on the front surface side of the substrate SUB and the wiring of the BSM1 layer. Thus, the control circuit CNTL and the switch transistor SWT can be arranged at positions separated from each other in a plan view.

FIG. 7 illustrates an example of a cross section taken along line X1-X1′ and a cross section taken along X2-X2′ in FIG. 6. In the cross section taken along the lines X1-X1′, the semiconductor layers (source, drain) of the inverters IV1 and IV2 of the control circuit CNTL are connected to the power supply line TVDD or the ground line VSS of the wiring layer PR via the via VIA4 formed in the substrate SUB. Although the wiring layer PR is arranged along the lower surface of the substrate SUB in FIG. 7, it may be arranged in the substrate SUB.

The wiring SIG for transmitting the output signal OUT that is output from the control circuit CNTL is connected to the wiring SIG of the wiring layer BSM1 from the signal tap cell STAP via the via VIA4, the wiring layer PR, and the via VIA3. The wiring SIG of the wiring layer BSM1 is connected to the gate GT(SWT) of the switch transistor SWT via the via VIA1 formed in an interlayer insulating film below the lower side of the wiring layer BSM1.

The gate GT(SWT) is provided at a position facing the channel of the switch transistor SWT via the gate insulating film GINS. The source and the drain of the switch transistor SWT provided on each side of the channel in the X direction are respectively connected to a power supply line TVDD and a virtual power supply line VVDD formed in the wiring layer BSM2.

The virtual power supply line VVDD of the wiring layer BSM2 connected to the power supply line TVDD via the switch transistor SWT is connected to the virtual power supply line VVDD of the wiring layer BSM1 via the via VIA1 in a cross section taken along line X2-X2′. The virtual power supply line VVDD of the wiring layer BSM1 is connected to the virtual power supply line VVDD of the wiring layer PR via the via VIA3. The virtual power supply line VVDD of the wiring layer PR is further connected to the semiconductor layer DIF(FS) of the standard cell SC or the power supply terminal of the standard cell SC via the via VIA4 in a cross section taken along the line X1-X1′.

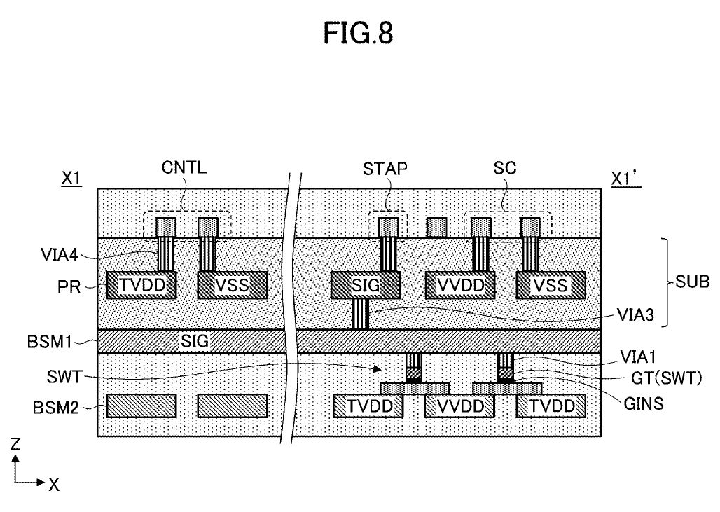

FIG. 8 illustrates another example of a cross section taken along line X1-X1′ in FIG. 6. Elements and layouts identical or similar to those of FIG. 7 are denoted by the same symbols or the same pattern, and detailed description thereof is omitted. The example illustrated in FIG. 8 is the same as the cross section taken along the line X1-X1′ of FIG. 7, except that the wiring of the wiring layer PR is formed in the substrate SUB and the wiring of the wiring layer BSM1 is formed at a position in contact with the back surface of the substrate SUB. The structure in which the wiring of the wiring layer PR is formed within the substrate SUB is also applicable to other embodiments or modified examples.

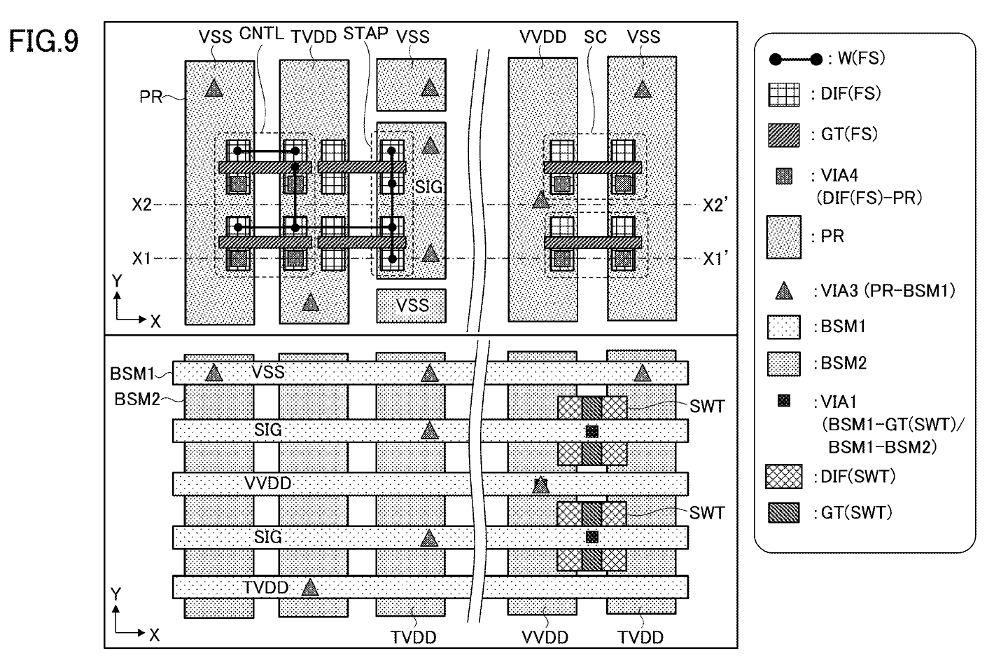

FIG. 9 illustrates a first modified example of the layout of the circuits and wirings illustrated in FIGS. 4 and 5. Elements and layouts identical or similar to those of FIG. 6 are denoted by the same symbols or the same pattern, and detailed description thereof is omitted.

FIG. 9 is the same as the layout in FIG. 6, except that the signal tap cell STAP is arranged adjacent to the control circuit CNTL. For example, the signal tap cell STAP may be arranged, together with the control circuit CNTL, in a power supply domain to which the power supply potential TVDD is always supplied.

Although FIG. 9 illustrates an example in which two switch transistors SWT are arranged, four switch transistors SWT may be arranged as in FIG. 6, or one, three, or five or more switch transistors SWT may be arranged. The layout illustrated in FIG. 9 may be applied to other embodiments or modified examples.

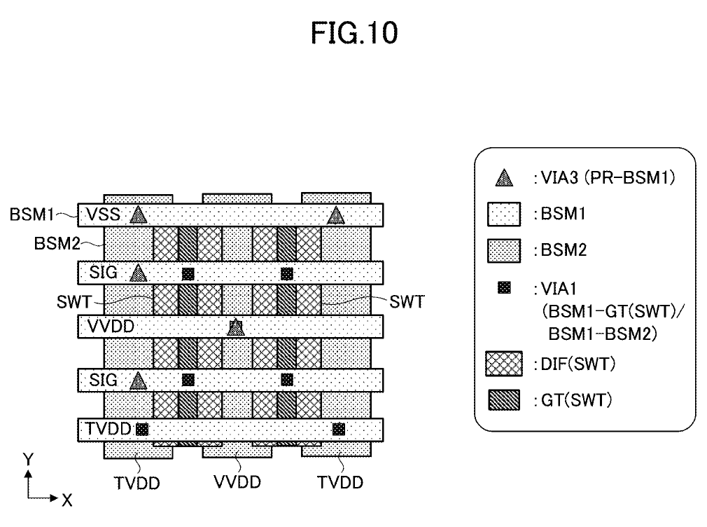

FIG. 10 illustrates a second modified example of the layout of the circuits and wirings illustrated in FIGS. 4 and 5. Elements and layouts identical or similar to those of FIG. 6 are denoted by the same symbols or the same pattern, and detailed description thereof is omitted. FIG. 10 illustrates only a region in which the switch transistor SWT is arranged in the region illustrated in FIG. 6, and the layout above the wiring layer PR is omitted.

In FIG. 10, the gate GT(SWT), the semiconductor layer DIF(SWT), and the gate insulating film GINS (not illustrated) of the switch transistor SWT are arranged to extend in the wiring direction of the wiring layer BSM2. Thus, the switch transistor SWT having a driving capability larger than that of the four switch transistors SWT illustrated in FIG. 6 can be arranged in a region having the same size as that in FIG. 6. The layout illustrated in FIG. 10 may be applied to other embodiments or modified examples.

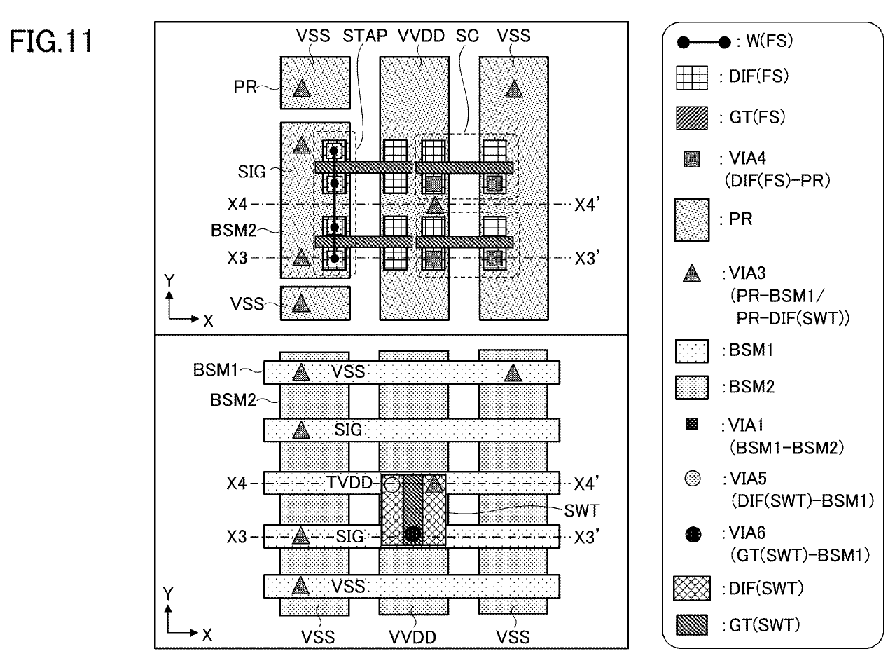

FIG. 11 illustrates a third modified example of the layout of the circuits and wirings illustrated in FIGS. 4 and 5. Elements and layouts identical or similar to those of FIG. 6 are denoted by the symbols or the same pattern, and detailed description thereof is omitted. FIG. 11 illustrates only a region in which the switch transistor SWT is arranged in the region illustrated in FIG. 6. The layout illustrated in the upper part of FIG. 11 is the same as the layout illustrated in the upper part of FIG. 6.

The layout illustrated in the lower part of FIG. 11 differs from the layout illustrated in the lower part of FIG. 6 in the type and arrangement of the wirings in the wiring layer BSM1. In FIG. 11, the switch transistor SWT is arranged between the wiring layer PR and the wiring layer BSM1. Although the gate GT(SWT) of the switch transistor SWT is arranged on the wiring layer BSM1 side with respect to the semiconductor layer DIF(SWT), FIG. 11 shows the gate GT(SWT) as if it is arranged on the semiconductor layer DIF(SWT) so that the position of the gate (SWT) can be easily identified. Although FIG. 11 illustrates an example in which one switch transistor SWT is arranged, a plurality of switch transistors SWT may be arranged as in other examples.

The drain (semiconductor layer DIF(SWT)) of the switch transistor SWT is connected to the virtual power supply line VVDD of the wiring layer PR via the via VIA3. The source (semiconductor layer DIF(SWT)) of the switch transistor SWT is connected to the power supply line TVDD of the wiring layer BSM1 via the via VIA5. The gate GT(SWT) of the switch transistor SWT is connected to the signal line SIG of the wiring layer BSM1 via the via VIA6.

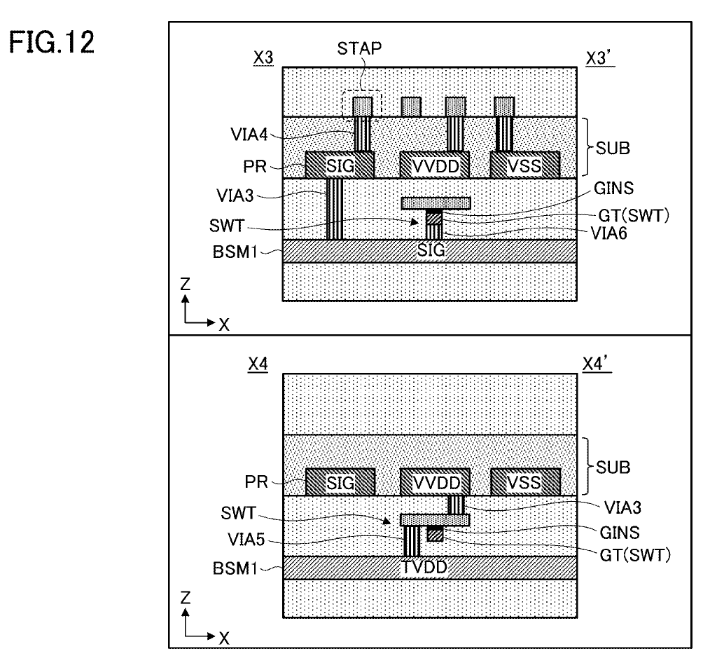

FIG. 12 illustrates an example of a cross section taken along line X3-X3′ and a cross section taken along X4-X4′ in FIG. 11. Elements and layouts identical or similar to those of FIG. 7 are denoted by the same symbols or the same pattern, and detailed description thereof is omitted.

Since the wiring of the wiring layer BSM2 is not connected to the switch transistor SWT, it is omitted from FIG. 12. The cross-sectional structure of the switch transistor SWT differs from that of the switch transistor SWT of FIG. 7 in that the top and bottom are inverted.

The gate GT(SWT) of the switch transistor SWT is connected to the signal line SIG of the wiring layer BSM1 in the cross section along line X3-X3′. The source and the drain of the semiconductor layer DIF(SWT) of the switch transistor SWT are connected to the power supply line TVDD of the wiring layer BSM1 and the virtual power supply line VVDD of the wiring layer PR in the cross section along the line X4-X4′.

As illustrated in the cross section along the line X4-X4′, the drain (VVDD) of the switch transistor SWT is directly connected to the virtual power supply line VVDD of the wiring layer PR via the via VIA3. Therefore, as illustrated in FIG. 12, a ground line VSS can be provided instead of the virtual power supply line VVDD of the wiring layer BSM1 in FIG. 6. In this way, for example, the number of the ground lines VSS of the wiring layer BSM1 can be increased as compared with FIG. 6, and the ground resistance can be therefore reduced. In the case where a power supply line TVDD is provided instead of the virtual power supply line VVDD of the wiring layer BSM1 in FIG. 6, the power supply resistance can be reduced.

The wiring and the switch transistor SWT located on the back surface side of the substrate SUB may be formed by bonding another semiconductor chip to the back surface of the substrate SUB. Alternatively, the wiring and the switch transistor SWT located on the back surface side of the substrate SUB may be formed by performing wafer processes, such as film formation, exposure processing, and etching on the back surface of the substrate SUB. The layout illustrated in FIGS. 11 and 12 may be applied to other embodiments or modified examples.

In the first embodiment, the signal tap cell STAP is provided in the circuit region on the front surface side of the substrate SUB where the transistor is provided by using the via VIA4 directly connected to the semiconductor layer, such as the source and drain of the transistor, from the back surface side of the substrate SUB. Therefore, even when the switch transistor SWT is arranged on the back surface of the substrate SUB, the signal SIG from the control circuit CNTL can be supplied to the gate of the switch transistor SWT without providing a region different from the circuit region, and the increase in the circuit area can be suppressed.

By arranging the wiring SIG of the PR layer in a region where the ground line VSS of the PR layer extending in the Y direction is interrupted, the region where the ground line VSS is arranged can be increased, and the ground resistance can be reduced, as compared with the case where the wiring SIG extends in the Y direction without interruption.

The signal SIG (output signal OUT0) is supplied from the control circuit CNTL to the gate GT(SWT) of the switch transistor SWT by using the wiring W provided on the front surface side of the substrate SUB and the wiring of the BSM1 layer. Thus, the control circuit CNTL and the switch transistor SWT can be arranged at positions separated from each other in a plan view.

### Second Embodiment

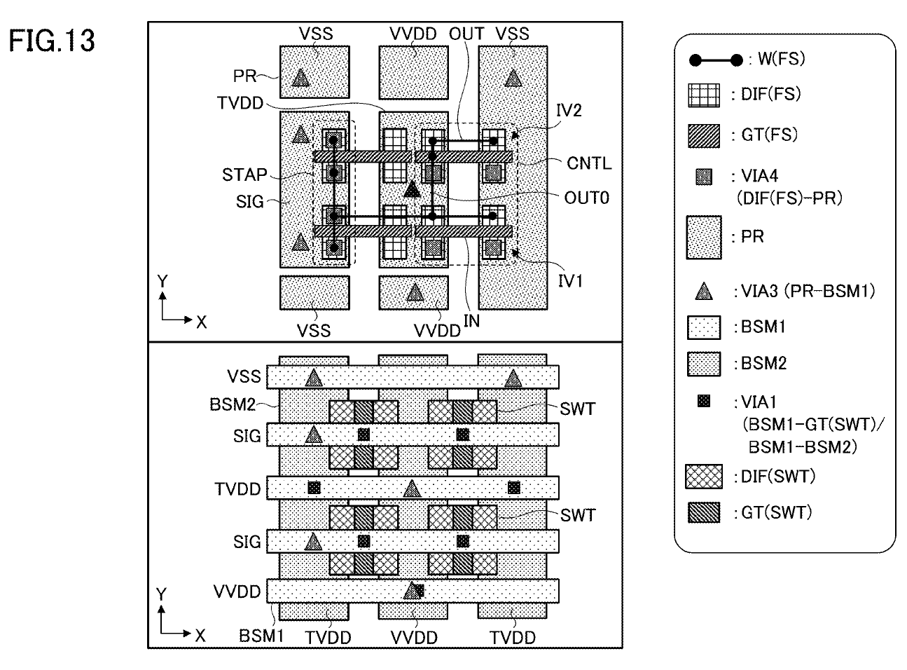

FIG. 13 illustrates an example of the layout of the circuits and wirings of the standard cell block in the semiconductor device of the second embodiment. Elements and layouts identical or similar to those of FIG. 6 are denoted by the same symbols or the same pattern, and detailed description thereof is omitted. In this embodiment, the control circuit CNTL is formed in a region where the standard cell SC is formed in FIG. 6. For example, the control circuit CNTL may be arranged in a power supply domain (power supply shutoff region) where supply of the virtual power supply potential VVDD can be stopped. The configuration of the control circuit CNTL is similar to that of the control circuit CNTL in FIG. 6.

The wiring SIG for transmitting the output signal OUT that is output from the control circuit CNTL is connected to the gate GT(SWT) of the switch transistor SWT via the wiring W(FS), the semiconductor layer DIF(FS) of the signal tap cell STAP, the via VIA4, the wiring SIG of the wiring layer PR, the wiring SIG of the wiring layer BSM1, and the via VIA1.

The transistors of the inverters IV1 and IV2 of the control circuit CNTL are, for example, a fin FET using fins, a planar MOSFET, a nanosheet FET, or a CFET. The ground potential VSS or the power supply potential TVDD is supplied to the transistors of the inverters IV1 and IV2 of the control circuit CNTL from the wiring of the wiring layer PR via the via VIA4, which is directly connected to the source and the drain, which are the semiconductor layers of the transistor.

In the layout illustrated in the upper side of FIG. 6 in FIG. 13, the power supply line TVDD is arranged between the signal line SIG of the wiring layer PR and the ground line VSS in the X direction, but the signal line SIG may be arranged between the power supply line TVDD and the ground line VSS, for example. In this case, the power supply line TVDD is arranged between the ground lines VSS interrupted in the Y direction, and the signal line SIG is arranged between the virtual power supply lines VVDD interrupted in the Y direction.

As described above, the second embodiment can also obtain effects similar to those of the first embodiment. For example, by connecting the control circuit CNTL and the gate GT(PSW) of the switch transistor SWT via the signal tap cell STAP, an increase in the circuit area can be suppressed. Furthermore, in the second embodiment, the control circuit CNTL and the switch transistor SWT can be arranged at positions at which they overlap in a plan view.

### Third Embodiment

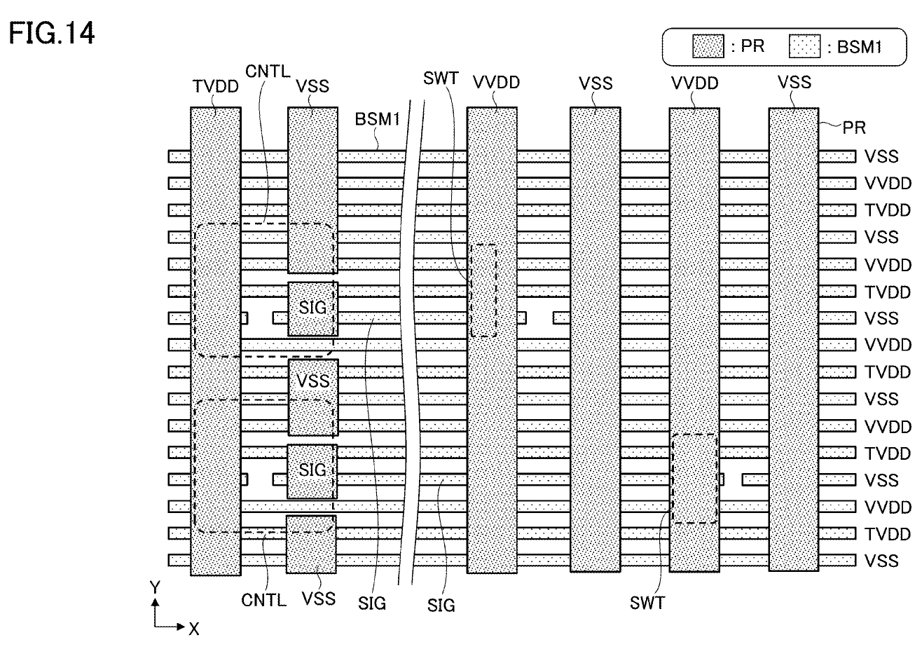

FIG. 14 illustrates an outline of a layout of a circuit and wiring of a standard cell block in a semiconductor device according to the third embodiment. Elements and layouts identical or similar to those of FIG. 4 are denoted by the same symbols or the same pattern, and detailed description thereof is omitted.

FIG. 14 differs from FIG. 4 in that the signal line SIG of the control circuit CNTL is formed by using the wiring layer BSM1 without using the wiring FS on the front surface side of the substrate SUB. The signal line SIG of the wiring layer BSM1 is arranged at a position for connecting the control circuit CNTL and the switch transistor SWT in a plan view, and electrically connects the control circuit CNTL and the gate GT (SWT) of the switch transistor SWT.

In the wiring layer BSM1, the ground line VSS is arranged in a region where the signal line SIG is not arranged. In other words, the ground line VSS is arranged in a region where the signal line SIG of the wiring layer BSM1 is interrupted. The ground line VSS interrupted at a plurality of locations and arranged in the wiring layer BSM1 is an example of a first wiring. The signal line SIG of the BSM1 layer arranged in a region where the signal line SIG is interrupted is an example of a second control line.

As illustrated in FIG. 14, by arranging the signal line SIG only in a necessary part of the wiring layer BSM1, for example, the ground line VSS can be arranged in a region where the signal line SIG is not arranged. The wiring SIG on the front surface FS side of the substrate SUB can be omitted. This makes it possible to efficiently arrange the wirings of the wiring layer BSM1 and the wirings of the standard cell SC.

Although not illustrated, in order to minimize the signal line SIG of the wiring FS on the front surface side of the substrate SUB, it is preferable that the signal tap cell STAP be arranged as a part of the control circuit CNTL or adjacent to the control circuit CNTL.

As described above, the third embodiment can also obtain effects similar to those of the first embodiment. For example, by connecting the control circuit CNTL and the gate GT(PSW) of the switch transistor SWT via the signal tap cell STAP, an increase in the circuit area can be suppressed. Furthermore, in the second embodiment, the control circuit CNTL and the switch transistor SWT can be arranged at positions at which they overlap in a plan view.

Furthermore, in the third embodiment, by arranging the signal line SIG only in a necessary part of the wiring layer BSM1, for example, the ground line VSS can be arranged in a region where the signal line SIG is not arranged. The wiring SIG on the front surface FS side of the substrate SUB can be omitted. This makes it possible to efficiently arrange the wirings of the wiring layer BSM1 and the wirings of the standard cell SC.

### Fourth Embodiment

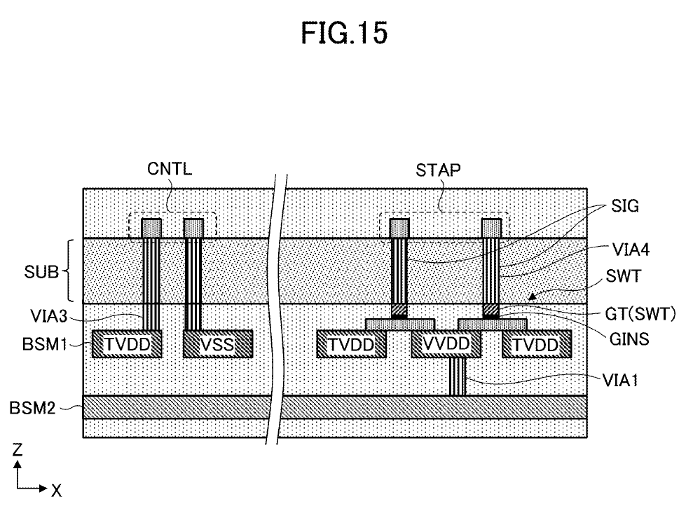

FIG. 15 illustrates an example of the layout of the circuits and wirings of the standard cell block in the semiconductor device of the fourth embodiment. Elements and layouts identical or similar to those of FIG. 7 are denoted by the same symbols or the same pattern, and detailed description thereof is omitted.

FIG. 15 differs from the other embodiments in that the semiconductor layer DIF (FS) of the signal tap cell STAP is directly connected to the gate GT (SWT) of the switch transistor SWT via the via VIA4 serving as the signal line SIG. Although not illustrated, the ground line VSS may be arranged in the wiring layer BSM1 below the signal tap cell STAP. In this case, like the PR layer in the other embodiments, the power supply line TVDD, the ground line VSS, and the virtual power supply line VVDD of the wiring layer BSM1 may be connected to a transistor or wiring formed on the front surface FS side of the substrate SUB via a via.

As described above, the fourth embodiment can also obtain effects similar to those of the first embodiment. For example, by connecting the control circuit CNTL and the gate GT(PSW) of the switch transistor SWT via the signal tap cell STAP, an increase in the circuit area can be suppressed. Furthermore, in the fourth embodiment, by directly connecting the semiconductor layer DIF (FS) of the signal tap cell STAP to the gate GT (SWT) of the switch transistor SWT via the via VIA4, an increase in the circuit area can be further suppressed.

Although the present disclosure has been described above based on the respective embodiments, the present disclosure is not limited to the requirements illustrated in the above embodiments. These points can be changed within a range not departing from the gist of the present disclosure, and can be appropriately determined according to the application form.

What is claimed is:

1. A semiconductor device, comprising:
a substrate;
a first power supply line to which a first potential is supplied and a second power supply line to which a second potential is supplied, the first power supply line and the second power supply line being formed below an upper surface of the substrate;
a first control line formed below the upper surface of the substrate;
a first transistor formed below the upper surface of the substrate, provided electrically between the first power supply line and the second power supply line, and having a gate electrically connected to the first control line;
a tap cell including
a semiconductor layer formed on the substrate, and
a via formed in the substrate, arranged at a position overlapping the semiconductor layer and the first control line in a plan view, and connected to the semiconductor layer and the first control line; and
a control circuit formed on the substrate and electrically connected to the via.

2. The semiconductor device according to claim 1, comprising:
a plurality of third power lines arranged to extend in a first direction in a plan view, wherein
the first control line is arranged in a region between the plurality of third power lines in the first direction.

3. The semiconductor device according to claim 1, wherein
the control circuit and the first transistor are arranged apart from each other in a plan view.

4. The semiconductor device according to claim 1, wherein
the control circuit and the first transistor are arranged so as to overlap each other in a plan view.

5. The semiconductor device according to claim 2, comprising:
a plurality of first wirings extending in a second direction differing from the first direction in a plan view below the first power supply line, the second power supply line, and the first control line; and
a second control line arranged between the plurality of first wirings in the second direction and electrically connected to the first control line and the gate of the first transistor.

6. The semiconductor device according to claim 5, wherein
the first wiring is electrically connected to the third power supply line.

7. The semiconductor device according to claim 1, wherein
the via is arranged at a position overlapping the gate of the first transistor in a plan view and directly connected to the gate.
